(19) United States
(12) Patent Application Publication
(10) Pub. No.: US 2018/0313988 A1
(43) Pub. Date: Nov. 1, 2018

(54) COLOR FILTER STRUCTURE AND FABRICATING METHOD THEREOF

(71) Applicant: HIMAX TECHNOLOGIES LIMITED, Tainan City (TW)

(72) Inventors: Yu-Jui HSIEH, Tainan City (TW); Po-Nan CHEN, Tainan City (TW)

(21) Appl. No.: 15/582,754

(22) Filed: Apr. 30, 2017

(51) Int. Cl. G02B 5/20; G03F 7/16; G03F 7/20

(52) U.S. Cl. CPC G02B 5/201; G03F 7/70; G03F 7/162

(57) ABSTRACT

A method for fabricating a color filter structure is provided. The method includes: coating a transparent photoresist to form a transparent photoresist layer on a wafer; performing a photolithography process to form a dummy coating layer, in which the dummy coating layer includes plural columnar transparent photoresists and plural trenches sandwiched between two adjacent columnar transparent photoresists; and coating a color filter into the trenches to form the color filter structure.

### BACKGROUND

### Field of Invention

The present invention relates to a method for fabricating a color filter structure. More particularly, the present invention relates to a fabricating method for reducing a striation defect of a color filter structure.

### Description of Related Art

A ladder-like pixel arrangement is one of the layout topographies for manufacturing a LCOS (Liquid Crystal on Silicon) device. However, the ladder-like pixel arrangement may induce a striation defect, because at least one coating layer which is previously coated above a wafer becomes an obstacle for subsequent coating layers. Therefore, there is a need to reduce the striation defect.

### SUMMARY

The present invention provides a method for fabricating a color filter structure. The method includes: coating a transparent photoresist to form a transparent photoresist layer on a wafer; performing a photolithography process to form a dummy coating layer, in which the dummy coating layer includes plural columnar transparent photoresists and plural trenches sandwiched between two adjacent columnar transparent photoresists; and coating a color filter into the trenches to form the color filter structure.

### BRIEF DESCRIPTION OF THE DRAWINGS

The invention can be more fully understood by reading the following detailed description of the embodiment, with reference made to the accompanying drawings as follows:

FIG. 1 is a flow chart showing a method for fabricating a color filter structure according to an embodiment of t he present invention.

FIGS. 2a-2e are cross-sectional views of the color filter structure respectively corresponding to the steps of the method for fabricating the color filter structure according to the embodiment of the present invention.

FIG. 3 is a top view of the color filter structure according to the embodiment of the present invention.

### DETAILED DESCRIPTION

Specific embodiments of the present invention are further described in detail below with reference to the accompanying drawings, however, the embodiments described are not intended to limit the present invention and it is not intended for the description of operation to limit the order of implementation. Moreover, any device with equivalent functions that is produced from a structure formed by a recombination of elements shall fall within the scope of the present invention. Additionally, the drawings are only illustrative and are not drawn to actual size.

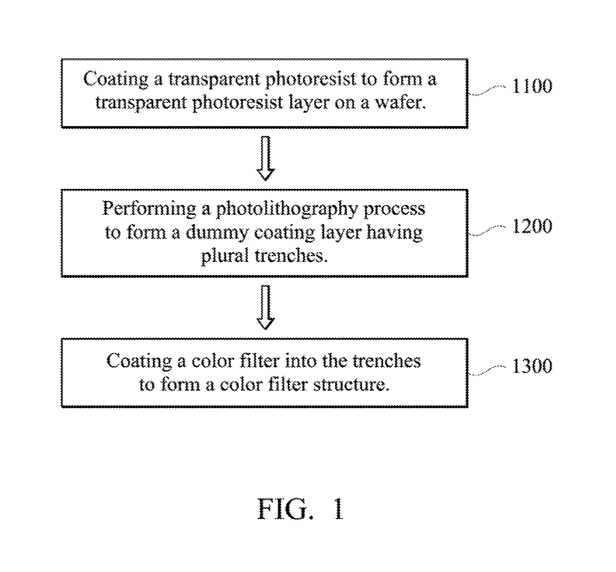

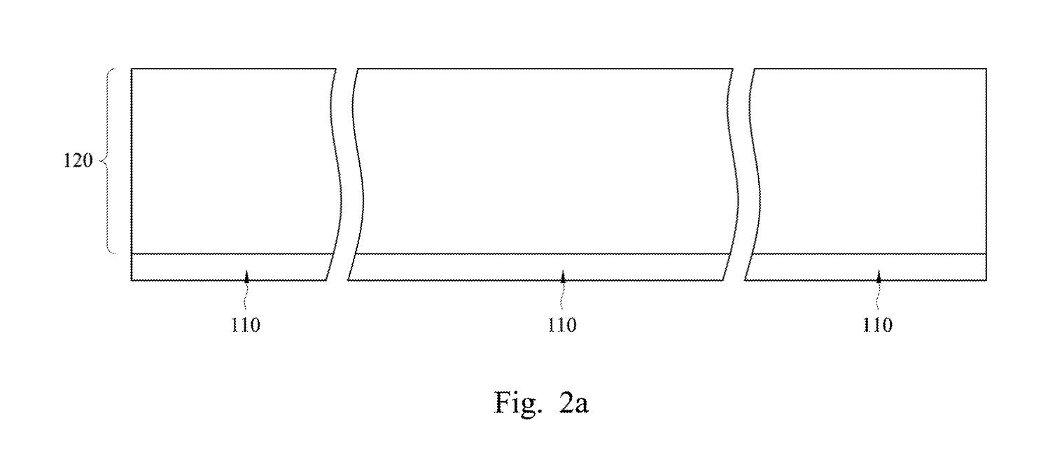

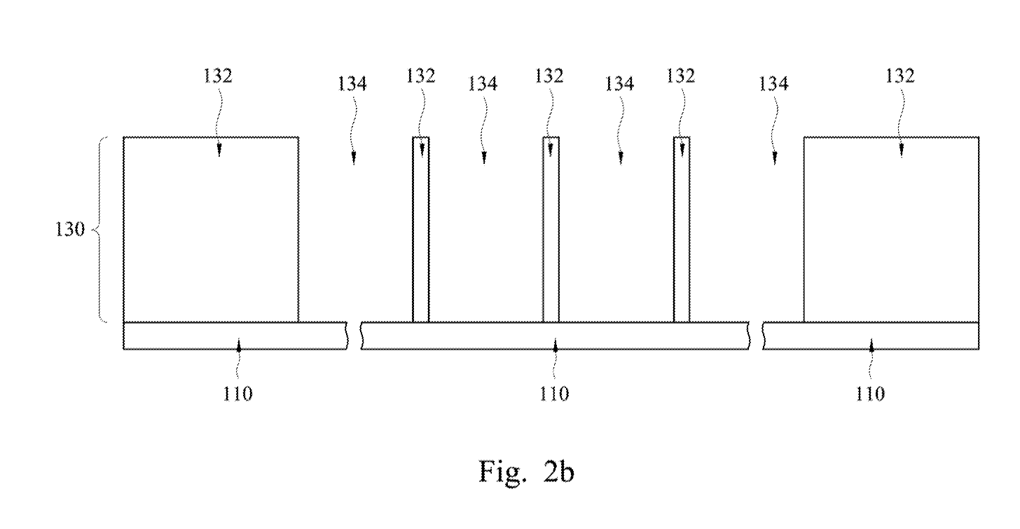

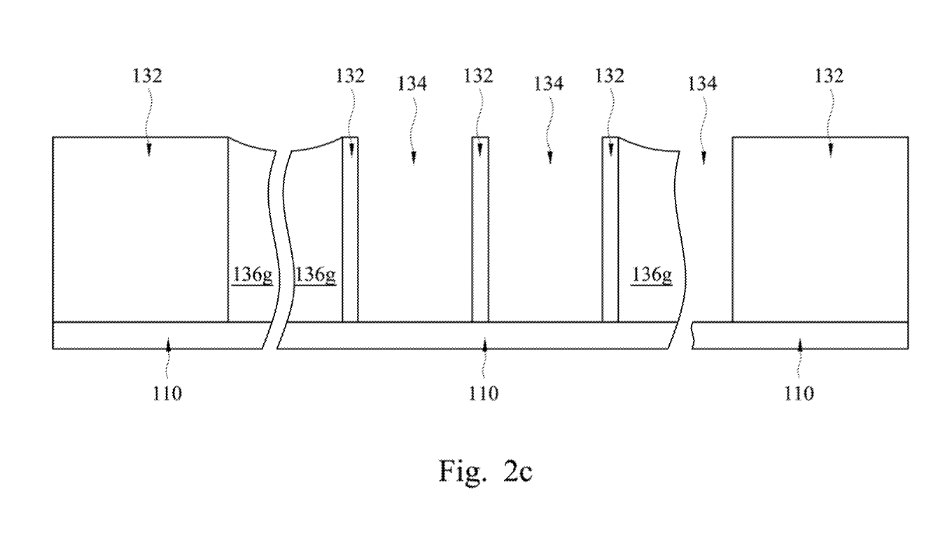

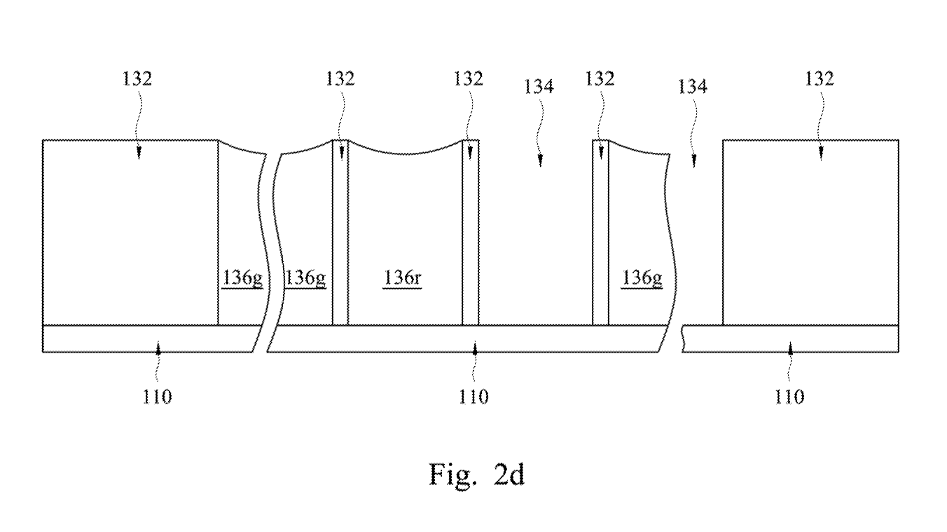

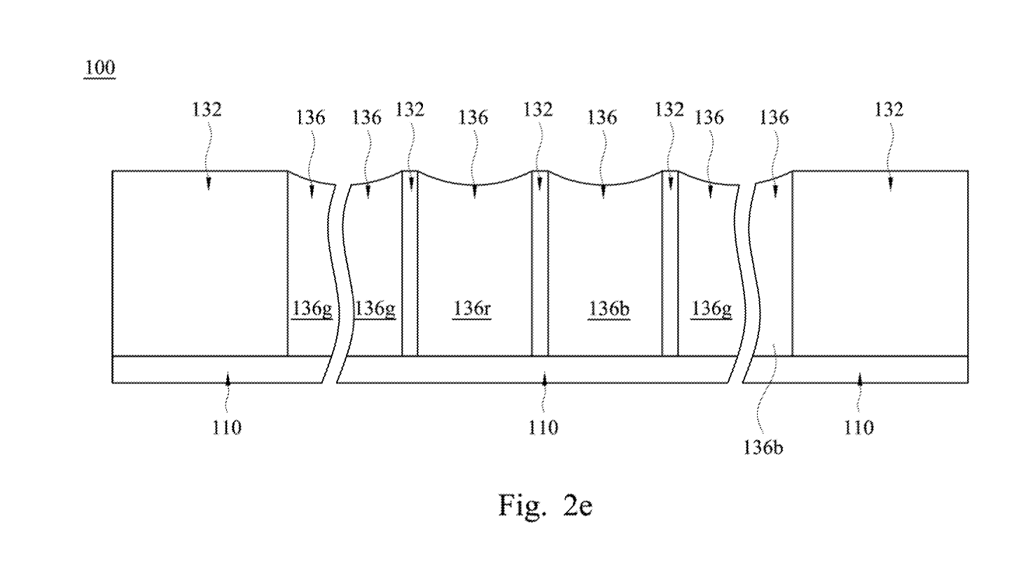

Referring to FIG. 11 and FIGS. 2a-2e, FIG. 1 is a flow chart showing a method 1000 for fabricating a color filter structure 100 according to an embodiment of the present invention and FIGS. 2a-2e are cross-sectional views of the color filter structure 100 respectively corresponding to the steps 1100-1300 of the method 1000 for fabricating the color filter structure 100 according to the embodiment of the present invention. The method 1000 starts from step 1100. In step 1100, a transparent photoresist is coated to form a transparent photoresist layer 120 on a wafer 110 as shown in FIG. 2a. In this embodiment, the transparent photoresist is a positive photoresist, but embodiments of the present invention are not limited thereto.

As shown in FIG. 2b, in step 1200 of the method 1000, a photolithography process is performed on the transparent photoresist layer 120 to form a dummy coating layer 130. Specifically, the transparent photoresist layer 120 is selectively etched to form the dummy coating layer 130. The dummy coating layer 130 includes plural columnar transparent photoresists 132 and plural trenches 134. Each of the trenches 134 is sandwiched between two adjacent columnar transparent photoresists.

As shown in FIGS. 2c-2e, in step 1300 of the method 1000, a color filter 136 is coated into the trenches 134 to form the color filter structure 100, in which the color filter 136 is coated by performing a spin coating process. The color filter 136 is configured to provide a color light. In this embodiment the color filter 136 includes plural green color filter unit 136g, plural red color filter units 136r and plural blue color filter units 136b. In this embodiment, the green color filter unit 136g, the red color filter units 136r and the blue color filter units 36b are sequentially coated as shown in FIGS. 2c-2e, but embodiments of the present invention are not limited thereto.

The columnar transparent photoresists 132 are configured to allow the passage of the color light. Therefore, the columnar transparent photoresists 132 do not affect the color light passing the color filter 136. It is noted that the color filter structure 100 is arranged as a ladder-like structure.

Specifically, the dummy coating layer 130 provides plural trenches 134 for the color filter 136 to be filled in, thereby reducing the obstacle for the color filter 136. Therefore, the color filter structure 100 of the present invention has a smaller striation ratio. Furthermore, the spin coating process allows a top surface of the color filter 136 to be a circular-arc-shaped as shown in FIG. 2e. Although a thickness of the color filter 136 is slightly less than the thickness of the columnar transparent photoresists 132, a difference of the thicknesses as mentioned above is within an acceptable range. It is worth mentioning that the a spin coating speed of the spin coating process needs to be controlled to an appropriate value, such that a thickness of the color filter 136 is nearly the same as the thickness of the columnar transparent photoresists 132.

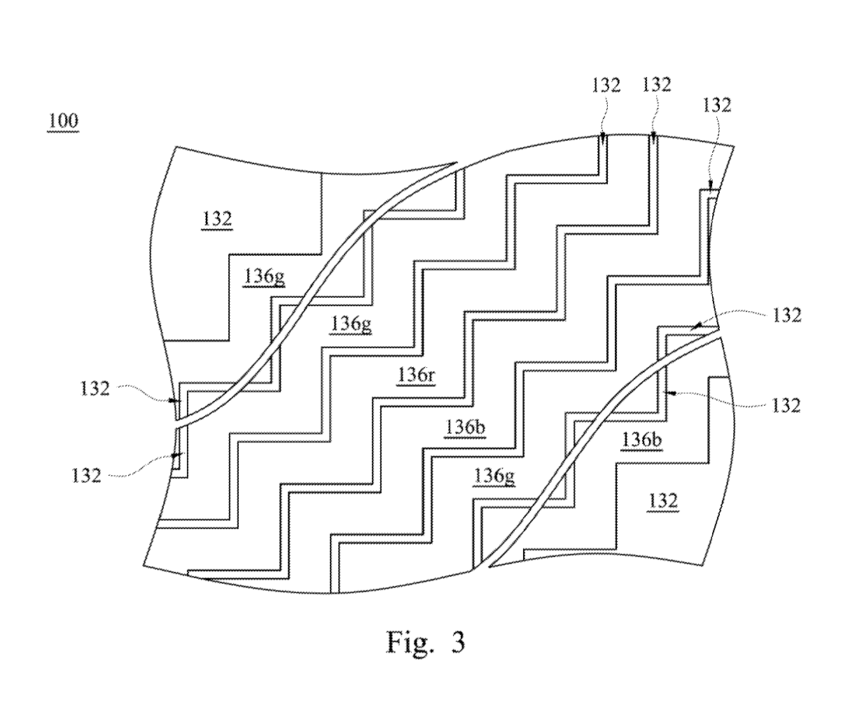

FIG. 3 is a top view of the color filter structure 100 according to the embodiment of the present invention. The green color filter unit 136g, the red color filter units 136r, the blue color filter units 136b and columnar transparent photoresists 132 are arranged as shown in FIG. 3. Thus, the color filter structure 100 is arranged as a larder-like structure. It is noted that FIG.3 is only illustrative, but embodiments of the present invention are not limited thereto.

From the above description, the method for fabricating the color filter structure of the present invention may reduce the striation defect. The present invention also provides a color filter structure fabricated by the method as mentioned above. The color filter structure of the present invention may reduce the striation defect.

Although the present invention has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A method for fabricating a color filter structure, comprising:
coating a transparent photoresist to form a transparent photoresist layer on a wafer;
performing a photolithography process to form a dummy coating layer, wherein the dummy coating layer comprises a plurality of trenches and a plurality of columnar transparent photoresists, wherein the trenches, sandwiched between two adjacent columnar transparent photoresists; and
coating a color filter into the trenches to form to color filter structure.

2. The method of claim 1, wherein the transparent photoresist is a positive photoresist.

3. The method of claim 1, wherein the color filter comprises a plurality of red color filter units, a plurality of green color filter units, and a plurality of blue color filter units.

4. The method of claim 1, wherein the color filter structure is arranged as a ladder-like structure.

5. The method of claim 1, wherein coating the color filter into the trenches is performed by a spin coating process.

6. A color filter structure comprising:
a wafer;
a plurality of columnar transparent photoresists disposed on the wafer; and
a plurality of color filter units disposed on the wafer;
wherein the color filter units are sandwiched between two adjacent columnar transparent photoresists.

7. The color filter structure of claim 6, wherein each of the columnar transparent photoresists is positive photoresist.

8. The color filter structure of claim 6, wherein the color filter units comprise a plurality of red color filter units, a plurality of green color filter units, and a plurality of blue color filter units.

9. The color filter structure of claim 6, wherein the color filter structure is arranged as a ladder-like structure.

10. The color filter structure of claim 6, wherein the color filter units are formed by a spin coating process.
